(19) United States
(12) Patent Application Publication
(10) Pub. No.: US 2010/0224425 A1
(43) Pub. Date: Sep. 9, 2010

(54) ELECTROMAGNETIC INPUT DEVICE

(75) Inventor: KIM-YEUNG SIP, Shenzhen City (CN)

Correspondence Address: PCE INDUSTRY, INC.;ATT. Steven Reiss, 288 SOUTH MAYO AVENUE, CITY OF INDUSTRY, CA, 91789, US

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/513,000

(22) Filed: Jul. 31, 2009

(30) Foreign Application Priority Data
Mar. 5, 2009 (CN) 200910300702.0

(51) Int. Cl. G08C 21/00; H03M 1/22

(52) U.S. Cl. 178/18.07; 341/5

(57) ABSTRACT

An electromagnetic input device includes a movable magnetized stylus, an inducting module, and a controller. The movable magnetized stylus is operable to generate a magnetic field. The inducting module includes a plurality of inducting cells, a plurality of gate lines, and a plurality of output lines. Each inducting cell includes a coil, and is operable to output a differential signal with a differential voltage according to the change of magnetic flux through the coil caused by the moving of the stylus. The gate lines are connected to the plurality of inducting cells. The output lines are connected to the plurality of inducting cells. The controller is connected to the gate lines and the output lines. The controller is operable to output gate signals to enable the inducting cells to output the differential signals, and convert the differential signals to digital signals.

### BACKGROUND

1. Technical Field

The present disclosure relates to input devices and, particularly, to an electromagnetic input device.

2. Description of Related Art

Recently, touch input devices such as touch screens are widely used in electronic devices. Generally, these touch input devices include a touch panel and a stylus for operating the touch panel. However, it's inconvenient to use such a touch input device, because the stylus has to always touch the touch panel when inputting. As such, the touch panel bears a risk of having scratches from the stylus and the image of the touch panel may not be clear due to the scratches on the touch panel.

Therefore, it is desirable to provide an electromagnetic input device which can overcome the above-mentioned problems.

### BRIEF DESCRIPTION OF THE DRAWINGS

FIG. 1 is a schematic view of an electromagnetic input device, according to an exemplary embodiment.

FIG. 2 is a schematic view of an inducting layer of the electromagnetic input device of FIG. 1.

FIG. 3 is a schematic view of an inducting cell of the inducting layer of FIG. 2.

FIG. 4 is a block diagram of the electromagnetic input device of FIG. 1.

FIG. 5 is a block diagram of an analog-digital converter of the electromagnetic input device of FIG. 1.

FIGS. 6-9 are schematic views of distribution of digital signals of the electromagnetic input device of FIG. 1 at different usage state.

### DETAILED DESCRIPTION

Embodiments of the disclosure will now be described in detail with reference to the drawings.

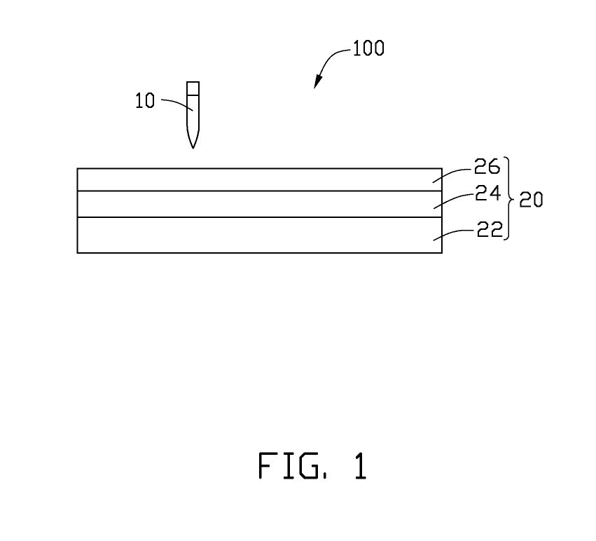

Referring to FIG. 1, an electromagnetic input device 100, according to an exemplary embodiment, includes a stylus 10 and an inducting module 20. In this embodiment, the stylus 10 is a magnetized pen, and the inducting module 20 is a touch screen, although any other input device such as a hand-writing panel is equally applicable while remaining well within the scope of the disclosure.

The inducting module 20 includes a substrate 22, an inducting layer 24, and a cover 26. The inducting layer 24 is sandwiched between the substrate 22 and the cover 26. In this embodiment, the inducting module 20 is transparent.

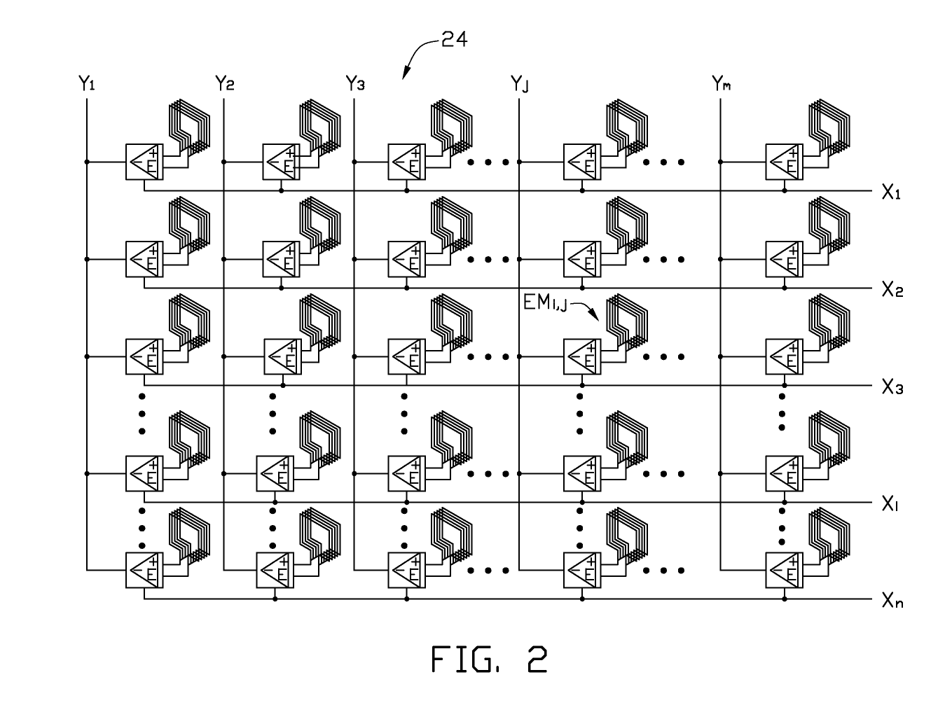

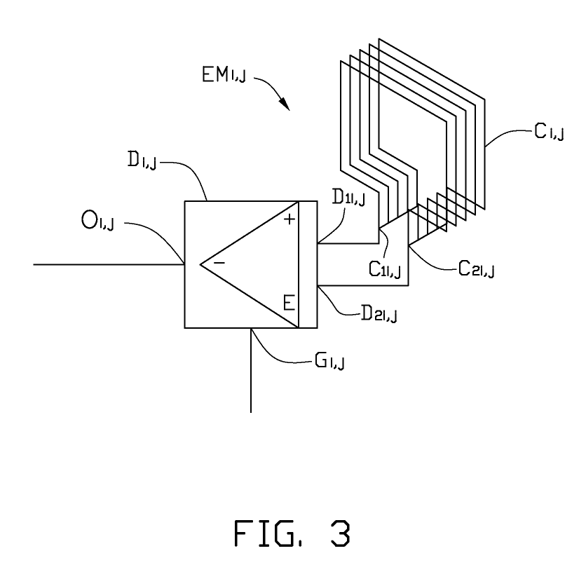

Referring to FIGS. 2-3, the inducting layer 24 includes n×m inducting cells EM_{i,j}, n gate lines X₁, and m output lines Yⱼ, where i=1, 2, . . . n, and j=1, 2, . . . m. Each inducting cell EM_{i,j} includes a coil C_{i,j} and a differential unit D_{i,j}.

The coil C_{i,j} includes a first output terminal C_{1i,j} and a second output terminal C_{2i,j}. The coil C_{i,j} is operable to sense the change of magnetic flux through the coil C_{i,j}, and generate a corresponding induced signal with an induced voltage. The induced voltage between the first and second output terminals C_{1i,j} and C_{2i,j} is proportional to the rate of the change of the magnetic flux through the coil C_{i,j}. In this embodiment, if the magnetic flux through the coil C_{i,j} increases, the induced voltage is positive and vice versa.

The differential unit D_{i,j} includes a first input terminal D_{1i,j,} a second input terminal D_{2i,j}, a third output terminal O_{i,j}, and a gate terminal G_{i,j}. The first and second input terminals D_{1i,j}, D_{2i,j} are connected to the first and second output terminals C_{1i,j}, C_{2i,j} to receive the induced signal respectively. The gate terminal G_{i,j} is connected to a gate line Xᵢ. The third output terminal O_{i,j} is connected to an output line Yⱼ. The gate terminal G_{i,j} is operable to receive a gate signal so as to enable the differential unit D_{i,j}. The third output terminal O_{i,j} is operable to output a differential signal with a differential voltage proportional to the induced voltage. In this embodiment, the induced voltage is amplified in the differential unit D_{i,j} such that the differential voltage is larger than the induced voltage.

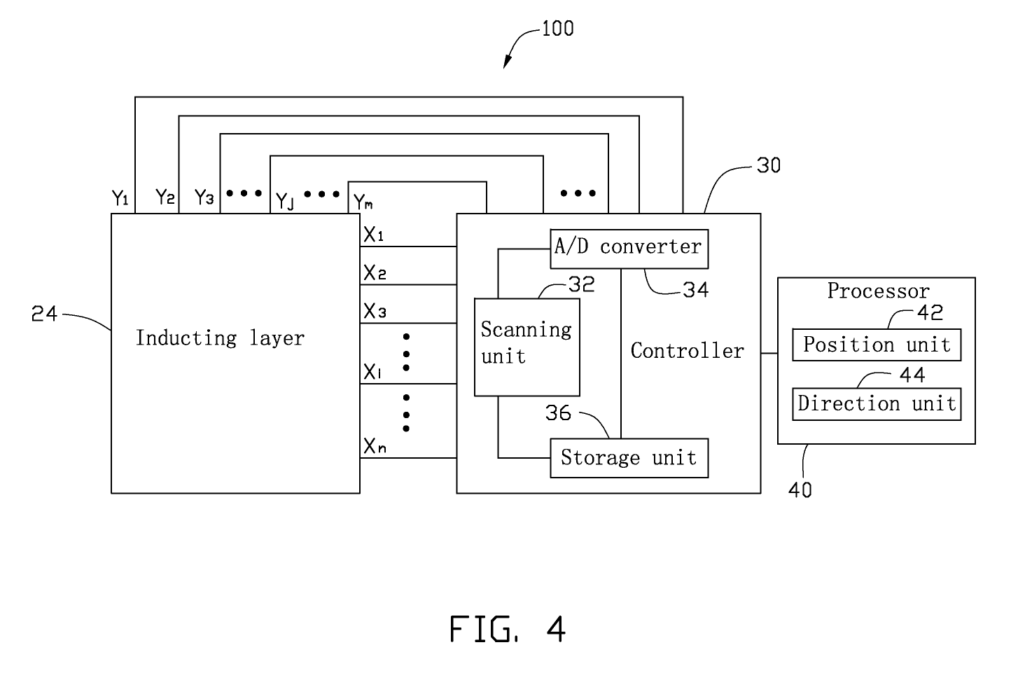

Referring to FIG. 4, the electromagnetic input device 100 further includes a controller 30 and a processor 40.

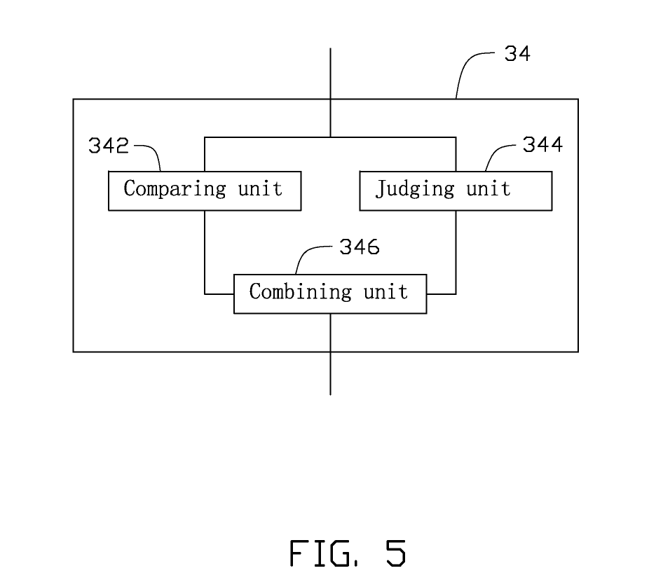

The controller 30 includes a scanning unit 32, an analog-to-digital (A/D) converter 34, and a storage unit 36. The scanning unit 32 is connected to the gate lines Xᵢ. Also referring to FIG. 5, the A/D converter 34 is connected to the output lines Yⱼ, and includes a comparing unit 342, a judging unit 344, and a combining unit 346. The storage unit 36 is connected to the scanning unit 32 and the A/D converter 34.

The scanning unit 32 is operable to output gate signals to the gate lines Xᵢ, line by line, to enable the differential units D_{i,j} to output the differential signals. The comparing unit 342 stores a pre-determined positive threshold voltage. In this embodiment, the threshold voltage is related to a threshold moving velocity of the stylus 10. The comparing unit 342 is operable to convert the differential signals to 1-bit magnitude digital signals according to the threshold voltage and the differential voltages outputted from the output lines Yⱼ. The judging unit 344 is operable to convert the differential signals to 1-bit polarity digital signals by detecting whether the differential voltages are positive or negative. The magnitude digital signals and the polarity digital signals are used for representing magnitudes and polarities of the differential voltages correspondingly. The magnitude digital signals include at least one first magnitude digital signal “1” and a plurality of second magnitude digital signals “0”. The polarity digital signals include first polarity digital signals “1” and second polarity digital signals “0”. The combining unit 346 is operable to combine each magnitude digital signal with a corresponding polarity digital signal to form a 2-bit digital signal, which corresponds to an inducting cell. The storage unit 36 includes a plurality of registers (not shown) for storing the digital signals generated by the A/D converter 34.

In this embodiment, the comparing unit 342 compares the differential voltages with the threshold voltage to find effective differential voltages having an absolute value larger than the threshold voltage. Then, the comparing unit 342 compares these effective differential voltages with each other to find target differential voltage(s) having the largest absolute value. Differential signal(s) having the target differential voltage(s) is(are) converted to the first magnitude digital signal(s) “1”, and other differential signals are converted to the second magnitude digital signals “0”. The judging unit 344 converts differential signals having positive differential voltages to the first polarity digital signals “1” and other differential signals to the second polarity digital signals “0” correspondingly. In the 2-bit digital signal formed by the combining unit 346, the first bit is a polarity digital signal, and the second bit is a magnitude digital signal.

It should be mentioned that, the comparing unit 342 can also firstly compare the differential voltages with each other to find target differential voltage(s) having the largest absolute value, and then compare the largest absolute value with the threshold voltage. If the largest absolute value is larger than the threshold voltage, then the differential signal(s) having the target differential voltage(s) is(are) converted to the first magnitude digital signal “1”, and other differential signals are converted to the second magnitude digital signals “0”. Otherwise, all the differential signals are converted to the second magnitude digital signals “0”.

The processor 40 is connected to the controller 30, and includes a position unit 42 and a direction unit 44. The position unit 42 is configured for determining a position of the stylus 10 on the inducting module 20 according to the digital signals stored in the storage unit 36. The direction unit 44 is configured for determining a moving direction of the stylus 10 according to the stored digital signals.

In use, the scanning unit 32 keeps outputting gate signals to the gate lines Xᵢ line by line, and the differential units D_{i,j} are enabled to output differential signals with differential voltages to the A/D converter 34 via the output lines Yⱼ. The A/D converter 34 converts the signals to 2-bit digital signals.

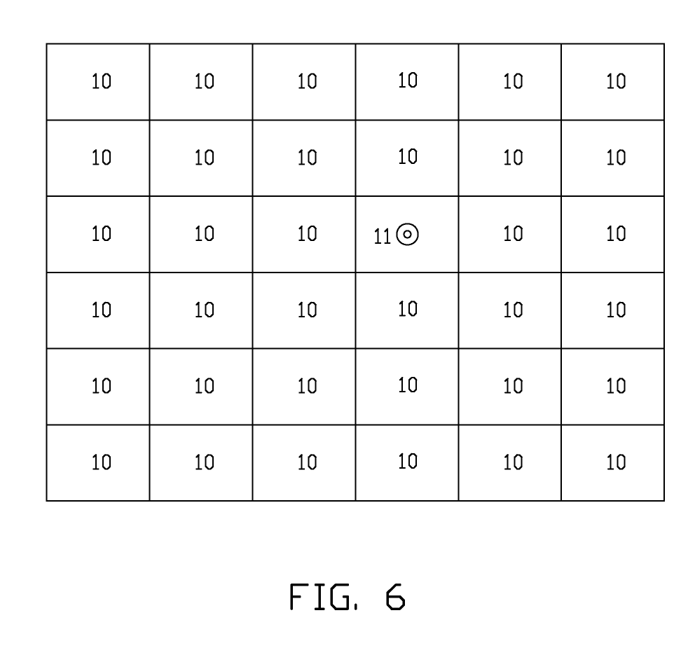

Referring to FIG. 6, if the stylus 10 points perpendicularly to an inducting cell EM_{i,j} with a moving velocity larger than the threshold moving velocity, the magnetic flux through the inducting cell EM_{i,j} increases, and the differential voltage V_{i,j} of the differential signal outputted by the differential unit D_{i,j} is positive and larger than the threshold voltage. In practice, the magnetic flux through the inducting cells EM_{i-1, j-1}, EM_{i-1,j}, EM_{i-1,j+1}, EM_{i,j-1}, EM_{i,j+1}, EM_{i+1,j-1}, EM_{i+1,j}, EM_{i+1,j+1}, which are around the inducting cell EM_{i,j}, may also increase caused by the emanative magnetic line of force, and the differential voltages V_{i-1,j-1}, V_{i-1,j}, V_{i-1,j+1}, V_{i,j-1}, V_{i,j+1}, V_{i+1,j-1}, V_{i+1,j}, V_{i+1,j+1} corresponding to these inducting cells may be larger than the threshold voltage too. The differential voltage of the inducting cell EM_{i,j} is positive and has the largest absolute value, and the differential signal of the inducting cell EM_{i,j} is converted to a digital signal “11”. Other differential signals are converted to “10”.

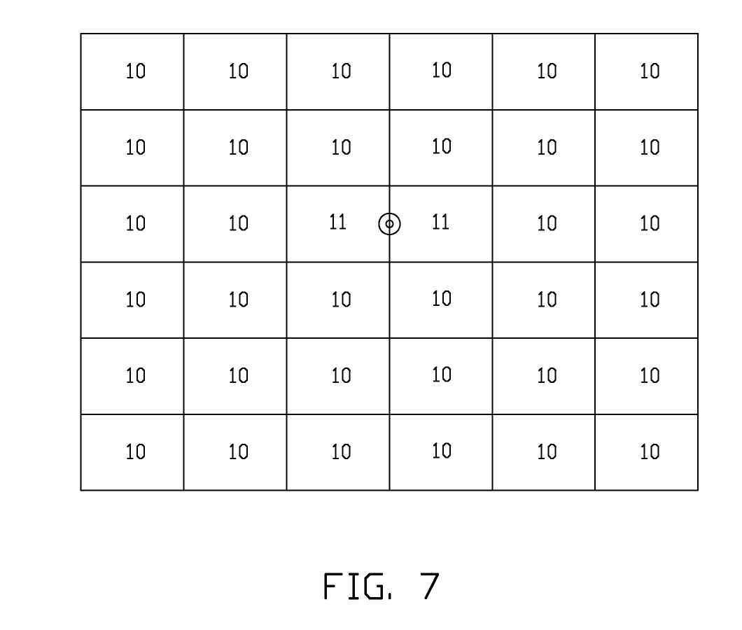

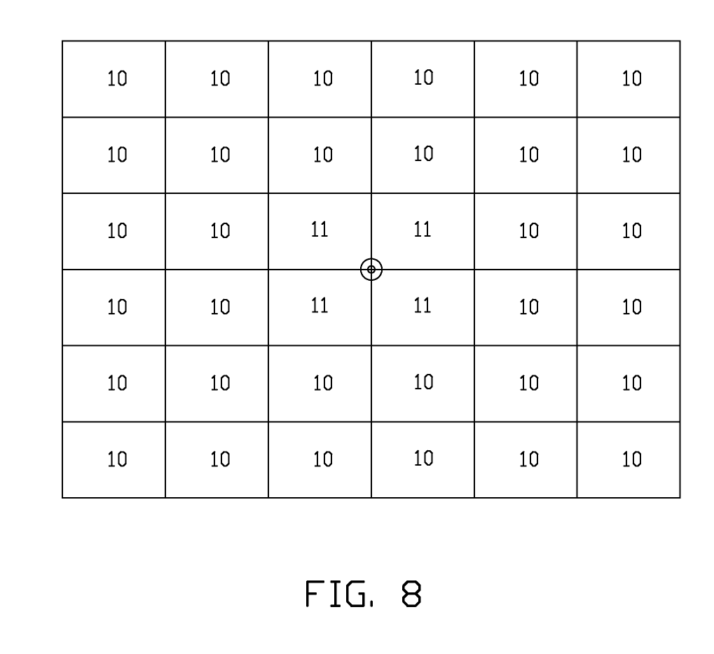

Referring to FIGS. 7-8, if the stylus 10 points perpendicularly to the intersecting line of the inducting cells EM_{i-1,j} and EM_{i,j}, or the intersection point of the inducting cells EM_{i-1,j}, EM_{i,j}, EM_{i-l,j-1}, and EM_{i,j-1}, then the differential signals of these inducting cells are converted to “11”, because all of the differential voltages of these inducting cells have the largest absolute value. Digital signals corresponding to other inducting cells are “10”.

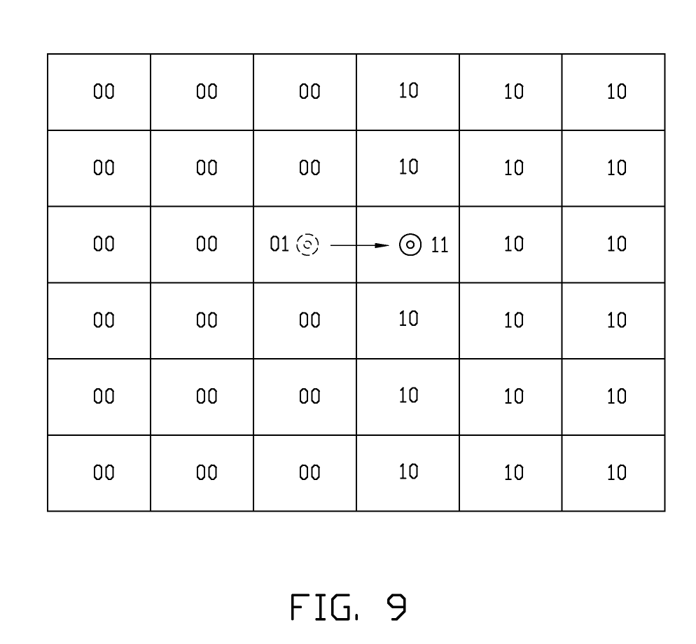

Then, referring to FIG. 9, if the stylus 10 moves from the inducting cell EM_{i, j} to EM_{i-1,j}, the magnetic flux through the inducting cell EM_{i,j} decreases, and the digital signal corresponding to the inducting cell EM_{i,j} changes from “11” to “01”. At the same time, the digital signals corresponding to the inducting cell EM_{i-1,j} changes from “00” to “11”, and the digital signal corresponding to the inducting cells in a direction opposite to the moving direction change from “10” to “00”. Otherwise, if the stylus 10 is kept unmoved, all the differential voltages are smaller than the threshold voltage because the magnetic flux through all the inducting cells is unchanged, and all the digital signals are “00” correspondingly.

If only one inducting cell has the digital signal “11”, then the position unit 42 determines that the stylus 10 is positioned on this inducting cell. If more than one inducting cell has the digital signal “11”, then the center of these inducting cells is determined as the position of the stylus 10. If no inducting cell having the digital signal “11”, then it is assumed that the stylus 10 is unmoved. The direction unit 44 determines the moving direction of the stylus 10 according to the change of the position of the stylus 10. Finally, the position and moving direction of the stylus 10 are inputted to an electronic device by the processor 40.

To compare with current touch input devices, the stylus 10 needn't to always touch the inducting module 20 when inputting, making inputting more convenient. Furthermore, this will decrease abrasion of the inducting module 20.

It is to be understood, however, that even though numerous characteristics and advantages of the present embodiments have been set forth in the foregoing description, together with details of the structures and functions of the embodiments, the disclosures are illustrative only, and changes may be made in details, especially in matters of arrangement of parts within the principles of the invention to the full extent indicated by the broad general meaning of the terms in which the appended claims are expressed.

What is claimed is:

1. An electromagnetic input device, comprising:
a movable magnetized stylus operable to generate a magnetic field;
an inducting module comprising:
a plurality of inducting cells, each inducting cell comprising a coil and being operable to output a differential signal with a differential voltage according to the change of magnetic flux through the coil caused by the moving of the stylus;
a plurality of gate lines connected to the plurality of inducting cells; and
a plurality of output lines connected to the plurality of inducting cells; and
a controller connected to the plurality of gate lines and the plurality of output lines, the controller being operable to output gate signals to enable the plurality of inducting cells to output the differential signals, and convert the differential signals to digital signals.

2. The electromagnetic input device as claimed in claim 1, wherein the coil is operable to generate an induced signal with an induced voltage when the magnetic flux through the coil is changed, the induced voltage being proportional to the rate of the change of the magnetic flux through the coil, the differential voltage being proportional to the induced voltage.

3. The electromagnetic input device as claimed in claim 1, wherein the coil comprises a first output terminal and a second output terminal, each inducting cell further comprising a differential unit, the differential unit comprising two input terminals, a third output terminal and a gate terminal, the two input terminals being connected to the first output terminal and the second output terminal correspondingly, the third output terminal being connected to an output line, the gate terminal being connected to a gate line, the differential unit being operable to output a differential signal with a differential voltage when the gate terminal receives a gate signal.

4. The electromagnetic input device as claimed in claim 1, wherein the controller comprises:
a scanning unit connected to the plurality of gate lines, the scanning unit being operable to output gate signals to the plurality of gate lines line by line to enable the plurality of inducting cells to output the differential signals; and
an analog-to-digital converter connected to the plurality of output lines, the analog-digital converter being operable to convert the differential signals to digital signals.

5. The electromagnetic input device as claimed in claim 4, wherein the controller comprises a storage unit connected to the scanning unit and the analog-to-digital converter, the storage unit being operable to store the digital signals.

6. The electromagnetic input device as claimed in claim 4, wherein the analog-to-digital converter comprises a comparing unit in which a pre-determined threshold voltage is stored, the comparing unit being operable to convert the differential signals to magnitude digital signals correspondingly via comparing the differential voltages with the threshold voltage.

7. The electromagnetic input device as claimed in claim 6, wherein the magnitude digital signals comprise at least one first magnitude digital signal and a plurality of second magnitude digital signals, the comparing unit being operable to compare the differential voltages with the threshold voltage to find effective differential voltages having an absolute value larger than the threshold voltage, then compare the effective differential voltages with each other to find a target differential voltage having the largest absolute value, and finally convert the differential signal having the target differential voltage to the first magnitude digital signal and other differential signals to the second magnitude digital signals.

8. The electromagnetic input device as claimed in claim 6, wherein the magnitude digital signals comprise at least one first magnitude digital signal and a plurality of second magnitude digital signals, the comparing unit being operable to compare the differential voltages with each other to find a target differential voltage having the largest absolute value, compare the largest absolute value with the threshold voltage, and convert the differential signal having the target differential voltage to the first magnitude digital signal and other differential signals to the second magnitude digital signals if the largest absolute value is larger than the threshold voltage.

9. The electromagnetic input device as claimed in claim 6, wherein the analog-to-digital converter further comprises a judging unit which is operable to convert the differential signals to polarity digital signals by detecting whether the differential voltages are positive or negative.

10. The electromagnetic input device as claimed in claim 9, wherein the polarity digital signals comprise first polarity digital signals and second polarity digital signals, the judging unit being operable to convert differential signals having positive effective differential voltages to the first polarity digital signals and other differential signals to the second polarity digital signals.

11. The electromagnetic input device as claimed in claim 9, wherein the analog-to-digital converter further comprises a combining unit connected to the comparing unit and the judging unit, the combining unit being operable to combine each magnitude digital signal with a corresponding polarity digital signal to form a combined digital signal which corresponds to an inducting cell.

12. The electromagnetic input device as claimed in claim 1, further comprising a processor connected to the controller, the processor comprising a position unit which is operable to determine the position of the stylus on the inducting module according to the digital signals generated by the controller.

13. The electromagnetic input device as claimed in claim 12, wherein the processor further comprises a direction unit which is operable to determine the moving direction of the stylus according to the change of the position determined by the position unit.

14. The electromagnetic input device as claimed in claim 1, wherein the inducting module comprises a substrate, an inducting layer disposed on the substrate, and a cover disposed on the inducting layer, the inducting layer comprising the plurality of inducting cells, the plurality of gate lines, and the plurality of output lines.

15. The electromagnetic input device as claimed in claim 14, wherein the inducting module is transparent.
